(19) United States
(12) Patent Application Publication
(10) Pub. No.: US 2026/0156920 A1
(43) Pub. Date: Jun. 4, 2026

(54) SEMICONDUCTOR DEVICE

(71) Applicant: FUJI ELECTRIC CO., LTD., Kanagawa (JP)

(72) Inventors: Yuuki ODA, Matsumoto-city (JP); Atsushi ONOGAWA, Matsumoto-city (JP); Tohru SHIRAKAWA, Matsumoto-city (JP); Kaname MITSUZUKA, Matsumoto-city (JP)

(21) Appl. No.: 19/457,150

(22) Filed: Jan. 23, 2026

Related U.S. Application Data
(63) Continuation of application No. PCT/JP2025/000734, filed on Jan. 10, 2025.

(30) Foreign Application Priority Data
Feb. 29, 2024 (JP) 2024-030797

(51) Int. Cl. H10D 84/00; H10D 12/00; H10D 62/17; H10D 62/53; H10D 64/00

(52) U.S. Cl. CPC H10D 84/161; H10D 12/415; H10D 12/481; H10D 62/393; H10D 62/53; H10D 64/117

(57) ABSTRACT

A semiconductor device including a transistor portion and a diode portion has a cathode region of the first conductivity type which is provided on a back surface of the semiconductor substrate and has a higher doping concentration than that of the drift region, and a collector region of the second conductivity type which is provided on the back surface of the semiconductor substrate and has a higher doping concentration than that of the base region, and includes a mixed portion where a transistor region below which the collector region is provided and a diode region below which the cathode region is provided are alternately provided in the trench extension direction.

The contents of the following patent application(s) are incorporated herein by reference:
NO. 2024-030797 filed in JP on Feb. 29, 2024
NO. PCT/JP 2025/000734 filed in WO on Jan. 10, 2025.

### BACKGROUND

### 1. Technical Field

The present invention relates to a semiconductor device.

### 2. RELATED ART

A semiconductor device having an IGBT region and an FWD region is known (for example, Patent Document 1).

### RELATED ART DOCUMENTS

### Patent Document

Patent Document 1: Japanese Patent Application Publication No. 2016-136620

### BRIEF DESCRIPTION OF THE DRAWINGS

FIG. 1 illustrates an example of a top view of a semiconductor device 100 according to the example.

FIG. 2 is an enlarged view which illustrates an example of a region A in FIG. 1.

FIG. 3A is a diagram which illustrates an example of a cross section a-a′ in FIG. 2.

FIG. 3B is a diagram which illustrates an example of a cross section b-b′ in FIG. 2.

FIG. 3C is a diagram which illustrates another example of a cross section a-a′ in FIG. 2.

FIG. 3D is a diagram which illustrates another example of a cross section a-a′ in FIG. 2.

FIG. 3E is a diagram which illustrates another example of a cross section a-a′ in FIG. 2.

FIG. 3F is a diagram which illustrates another example of a cross section a-a′ in FIG. 2.

FIG. 4A is an enlarged view which illustrates an example of a region B in FIG. 1.

FIG. 4B is a diagram which illustrates an example of a cross section c-c′ in FIG. 4A.

FIG. 4C illustrates an example of the arrangement of a collector region and a cathode region 82.

FIG. 5 is an enlarged view which illustrates another example of the region B in FIG. 1.

FIG. 6 is an enlarged view which illustrates yet another example of the region B in FIG. 1.

FIG. 7A is an enlarged view which illustrates another example of the region A in FIG. 1.

FIG. 7B is an enlarged view which illustrates yet another example of the region A in FIG. 1.

### DESCRIPTION OF EXEMPLARY EMBODIMENTS

The present invention will be described below through embodiments of the invention, but the following embodiments do not limit the invention according to the claims. Furthermore, not all of combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or some other member is referred to as a front surface, and the other surface is referred to as a back surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as a depth direction. In addition, in the present specification, a direction parallel to the front surface and the back surface of the semiconductor substrate may be referred to as a horizontal direction, including the X axis and the Y axis.

A region from a center in the depth direction of the semiconductor substrate to the front surface of the semiconductor substrate may be referred to as a front surface side. Similarly, a region from the center in the depth direction of the semiconductor substrate to the back surface of the semiconductor substrate may be referred to as a back surface side.

When a term such as “same” or “equal” is used herein, it may encompass a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type and may be described as dopants. In the present specification, doping means introducing the donors or the acceptors into the semiconductor substrate and turning it into a semiconductor presenting a conductivity type of the N type, or a semiconductor presenting a conductivity type of the P type.

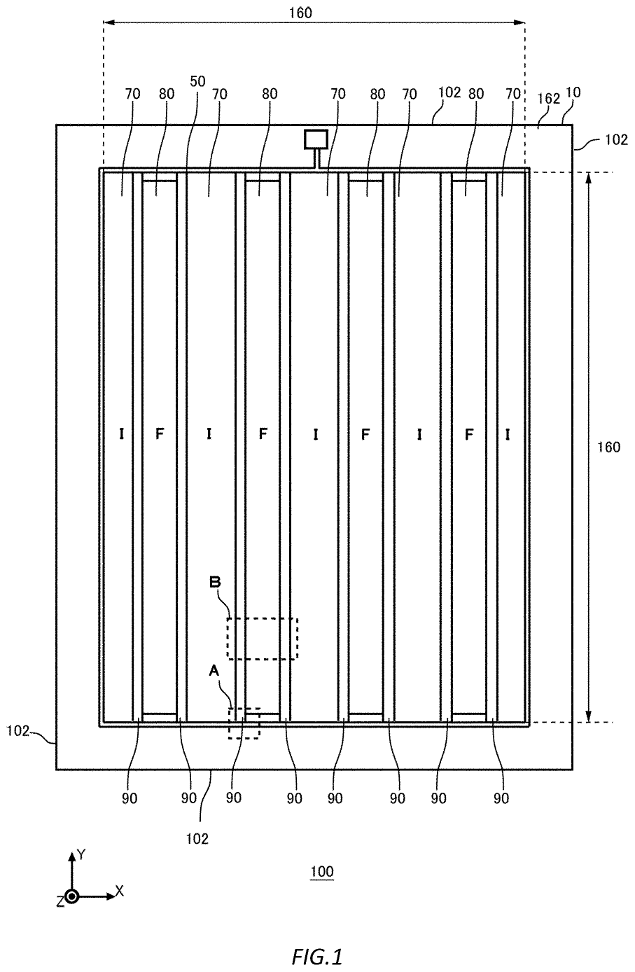

FIG. 1 illustrates an example of a top view of a semiconductor device 100 according to the example. FIG. 1 illustrates the position of each member as being projected onto the front surface of a semiconductor substrate 10. FIG. 1 illustrates merely some of the members of the semiconductor device 100, and omits illustrations of some of the members.

The semiconductor device 100 includes the semiconductor substrate 10. The semiconductor substrate 10 has an end side 102 in a top view. In the present specification, unless otherwise specified, a top view means a view from the front surface side of the semiconductor substrate 10. The semiconductor substrate 10 of the present example includes two sets of end sides 102 facing each other in a top view. In FIG. 1, the X axis and the Y axis are parallel to any of the end sides 102. In addition, the Z axis is perpendicular to the front surface of the semiconductor substrate 10.

In the semiconductor substrate 10, an active region 160 is provided. The active region 160 refers to a region where main currents flow in the depth direction between the front surface and the back surface of the semiconductor substrate 10, when the semiconductor device 100 is operated. Above the active region 160, an emitter electrode is provided, but it is omitted in FIG. 1.

The active region 160 is provided with a transistor portion 70 including a transistor device such as an IGBT and a diode portion 80 including a diode device such as a free wheel diode (FWD). For example, the semiconductor device 100 is a reverse conducting IGBT (RC-IGBT). Note that the semiconductor device 100 may be an IGBT or an MOS transistor.

In the example of FIG. 1, transistor portions 70 and diode portions 80 are alternately arranged along a predetermined arrangement direction (the X axis direction in the present example) of the front surface of the semiconductor substrate 10. However, in the X axis direction, the mixed portion 90 is provided between the transistor portion 70 and the diode portion 80. The mixed portion 90 will be described below.

In FIG. 1, a region where each of the transistor portions 70 is arranged is indicated by a symbol “I”, and a region where each of the diode portions 80 is arranged is indicated by a symbol “F”. In the present specification, a direction perpendicular to the arrangement direction in a top view may be referred to as an extension direction (the Y axis direction in FIG. 1). Each of the transistor portions 70 and the diode portions 80 may have a longitudinal length in the extension direction. In other words, the length of each of the transistor portions 70 in the Y axis direction is greater than the width in the X axis direction. Similarly, the length of each of the diode portions 80 in the Y axis direction is greater than the width in the X axis direction. The extension direction of the transistor portion 70 and the diode portion 80, and the longitudinal direction of each trench portion described below may be the same.

In FIG. 1, the end of the transistor portion 70 in the Y axis direction is positioned closer to the end side 102 than the end of the diode portion 80 in the Y axis direction. In addition, the width of the transistor portion 70 in the X axis direction is greater than the width of the diode portion 80 in the X axis direction.

The diode portion 80 has a cathode region of the N+ type in a region in contact with the back surface of the semiconductor substrate 10. In the present specification, a region provided with the cathode region and extending in the Y axis direction is referred to as a diode portion 80. In the present specification, the diode portion 80 may also include an extension region which extends from the diode portion 80 to the edge termination structure portion 162 described below in the Y axis direction. The collector region is provided on the back surface of the extension region.

The transistor portion 70 includes a collector region of the P+ type in a region in contact with the back surface of the semiconductor substrate 10. In the present specification, the region provided with the collector region and extending in the Y axis direction is referred to as a transistor portion 70. In the transistor portion 70, an emitter region of N type, a base region of P type, and a gate trench portion having a gate conductive portion and a gate dielectric film are periodically arranged on the front surface side of the semiconductor substrate 10.

The semiconductor device 100 may have one or more pads above the semiconductor substrate 10. As an example, the semiconductor device 100 may have a pad such as a gate pad, an anode pad, a cathode pad, and a current detection pad (a current sensing portion). Each pad is arranged in the vicinity of the end side 102. The vicinity of the end side 102 refers to a region between the end side 102 and the emitter electrode, in a top view. When the semiconductor device 100 is mounted, each pad may be connected to an external circuit through a wiring such as a wire.

The gate metal layer 50 is arranged between the active region 160 and the end side 102 of the semiconductor substrate 10 in a top view. The gate metal layer 50 connects the gate trench portion and the gate pad. The gate metal layer 50 of the present example surrounds the active region 160 in a top view. A region surrounded by the gate metal layer 50 in a top view may be referred to as the active region 160.

It is noted that the middle part of the active region 160 may include a temperature sensing diode and the temperature sensing diode may be connected to the anode pad and the cathode pad.

The semiconductor device 100 of the present example includes an edge termination structure portion 162 between the active region 160 and the end side 102. The edge termination structure portion 162 of the present example is arranged between the gate metal layer 50 and the end side 102. The edge termination structure portion 162 reduces concentration of electric fields at the front surface side of the semiconductor substrate 10. The edge termination structure portion 162 may include a plurality of guard rings. The guard ring is a region of the P type in contact with the front surface of the semiconductor substrate 10. By providing the plurality of guard rings, it is possible to extend a depletion layer on the side of the upper surface of the active region 160 outward. The withstand voltage of the semiconductor device 100 can be improved. The edge termination structure portion 162 may further include at least one of a field plate and an RESURF provided in a circular form surrounding the active region 160.

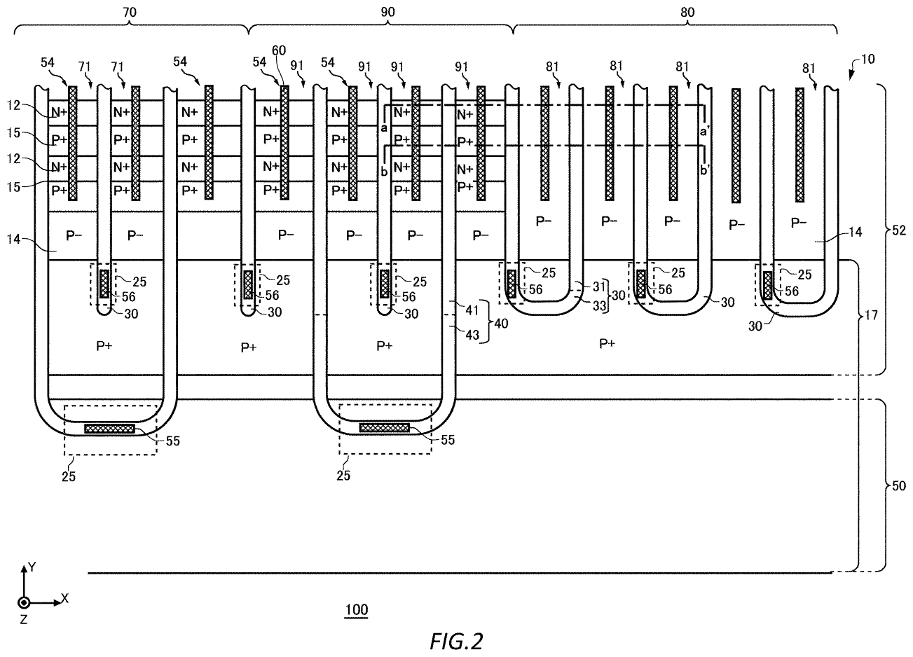

FIG. 2 is an enlarged view which illustrates an example of a region A in FIG. 1. The region A is a region spanning the transistor portion 70, the mixed portion 90, and the diode portion 80 at the edge side on the negative side in the Y axis direction of the semiconductor device 100 in the top view. It is noted that the structure of the front surface of the mixed portion 90 is approximately the same as the front surface structure of the transistor portion 70 in the area illustrated in FIG. 2 and is not described, except for the differences.

The transistor portion 70 is a region where the collector region 22 is provided on the back surface side of the semiconductor substrate 10. The collector region 22 in the present example is of the P+ type as an example. The transistor portion 70 includes transistors such as IGBTs.

The diode portion 80 is a region where the cathode region 82 is provided on the back surface side of the semiconductor substrate 10. The cathode region 82 of the present example is of N+ type, as an example. The diode portion 80 includes a diode such as a free wheel diode (FWD) provided adjacent to the transistor portion 70 in the front surface of the semiconductor substrate 10.

The semiconductor substrate 10 may be a silicon substrate, may be a silicon carbide substrate, or may be a nitride semiconductor substrate, such as a gallium nitride semiconductor substrate, or the like. The semiconductor substrate 10 in the present example is the silicon substrate.

The semiconductor device 100 in the present example includes a gate trench portion 40, a dummy trench portion 30, an emitter region 12, a base region 14, a contact region 15, and a well region 17, in the front surface of the semiconductor substrate 10. Also, the semiconductor device 100 of the present example includes an emitter electrode 52 and the gate metal layer 50, which are provided above the front surface of the semiconductor substrate 10.

The emitter electrode 52 is provided above the gate trench portion 40, the dummy trench portion 30, the emitter region 12, the base region 14, the contact region 15, and the well region 17. In addition, the gate metal layer 50 is provided above the gate trench portion 40 and the well region 17.

The emitter electrode 52 and the gate metal layer 50 are formed of a material including metal. At least some regions of the emitter electrode 52 may be formed of aluminum, aluminum-silicon alloy, or aluminum-silicon-copper alloy. At least some regions of the gate metal layer 50 may be formed of aluminum, aluminum-silicon alloy, or aluminum-silicon-copper alloy. The emitter electrode 52 and the gate metal layer 50 may include a barrier metal formed of titanium, titanium compound, or the like under the region formed of aluminum or the like. The emitter electrode 52 and the gate metal layer 50 are provided separately from each other.

The emitter electrode 52 and the gate metal layer 50 are provided above the semiconductor substrate 10, with the interlayer dielectric film 38 sandwiched therebetween. The interlayer dielectric film 38 is omitted from FIG. 2. A contact hole 54, a contact hole 55, and a contact hole 56 are provided to penetrate through the interlayer dielectric film 38.

The contact hole 55 connects the gate conductive portion in the gate trench portion 40 of the transistor portion 70 to the gate metal layer 50. In the contact hole 55, a plug formed of tungsten or the like may be formed via the barrier metal.

The contact hole 56 connects a dummy conductive portion in the dummy trench portion 30 provided in the transistor portion 70 and the diode portion 80 to the emitter electrode 52. In the contact hole 56, a plug formed of tungsten or the like may be formed via the barrier metal.

A connecting portion 25 electrically connects the emitter electrode 52 or a front surface side electrode of the gate metal layer 50 or the like with the semiconductor substrate 10. In an example, the connecting portion 25 is provided in the region including the interior of the contact hole 55 between the gate metal layer 50 and the gate conductive portion. The connecting portion 25 is also provided in a region including the interior of the contact hole 56, between the emitter electrode 52 and the dummy conductive portion. The connecting portion 25 is formed of a conductive material including a metal such as tungsten or the like and polysilicon doped with impurities. In addition, the connecting portion 25 may also have barrier metal such as titanium nitride. Herein, the connecting portion 25 is polysilicon (N+) doped with N type impurities. The connecting portion 25 is provided above the front surface of the semiconductor substrate 10, with a dielectric film such as oxide film or the like interposed therebetween.

The gate trench portion 40 is arranged at a predetermined interval along a predetermined arrangement direction (the X axis direction in the present example). The gate trench portion 40 in the present example may have two extension portions 41 extending along the extension direction (in the present example, the Y axis direction) that is parallel to the front surface of the semiconductor substrate 10 and perpendicular to the arrangement direction and a connecting portion 43 connecting the two extension portions 41.

At least a part of the connecting portion 43 is preferably formed in a curved shape. By connecting the ends of the two extension portions 41 of the gate trench portions 40, the concentration of electric field at the end of the extension portions 41 can be reduced. At the connecting portion 43 of the gate trench portion 40, the gate metal layer 50 may be connected to the gate conductive portion.

The dummy trench portion 30 is a trench portion in which the dummy conductive portion provided therein is electrically connected to the emitter electrode 52. The dummy trench portion 30 is arranged, similarly to the gate trench portion 40, at a predetermined interval along a predetermined arrangement direction (the X axis direction in the present example). The dummy trench portion 30 of the present example may have, similar to the gate trench portion 40, a U shape at the front surface of the semiconductor substrate 10. That is, the dummy trench portion 30 may include two extension portions 31 which extend along the extension direction and a connecting portion 33 which connects the two extension portions 31.

The transistor portion 70 in the present example has a repetitive arrangement structure of two gate trench portions 40 and three dummy trench portions 30. That is, the transistor portion 70 in the present example includes the gate trench portions 40 and the dummy trench portions 30 at a ratio of 2:3. For example, the transistor portion 70 includes one extension portion 31 between two extension portions 41. In addition, the transistor portion 70 includes two extension portions 31 adjacent to the gate trench portion 40.

It is noted that the ratio of the gate trench portions 40 and the dummy trench portions 30 is not limited to the present example. The ratio of the gate trench portions 40 and the dummy trench portions 30 may be 1:1 or may be 2:4. In addition, the transistor portion 70 may be entirely provided with the gate trench portion 40 without being provided with the dummy trench portion 30.

The well region 17 is provided to be closer to the front surface side of the semiconductor substrate 10 than the drift region 18 which will be described below. The well region 17 is an example of a well region provided on the edge side of the semiconductor device 100. The well region 17 is of the P+ type as an example. The well region 17 is provided in a predetermined range from the end of the active region 160 on the side where the gate metal layer 50 is provided. A diffusion depth of the well region 17 may be deeper than the depths of the gate trench portion 40 and the dummy trench portion 30. Some regions of the gate trench portion 40 and the dummy trench portion 30 on the gate metal layer 50 side are provided in the well region 17. Bottoms of ends of the gate trench portion 40 and the dummy trench portion 30 in the extension direction may be covered with the well region 17.

In the transistor portion 70, the contact hole 54 is provided above each region of the emitter region 12 and the contact region 15. The contact hole 54 is provided above the base region 14 in the diode portion 80. No contact holes 54 are provided above the well regions 17 provided at both ends in the Y axis direction. In this manner, the interlayer dielectric film includes one or more contact holes 54 formed therein. One or more contact holes 54 may be provided to extend in the extension direction.

Below the contact hole 54, a contact trench portion 60 is provided, which extends from the front surface of the semiconductor substrate 10 in the depth direction of the semiconductor substrate 10 (the Z axis direction in the present example). The contact trench portion 60 electrically connects the emitter electrode 52 and the semiconductor substrate 10. The contact trench portion 60 is provided to extend in the Y axis direction in the top view. That is, the contact trench portion 60 is arranged in a stripe pattern along the gate trench portion 40 and the dummy trench portion 30.

The mesa portion 71, the mesa portion 81 and the mesa portion 91 are mesa portions provided adjacent to the trench portions, in a plane parallel to the front surface of the semiconductor substrate 10. The mesa portion is a portion of the semiconductor substrate 10 interposed between two trench portions adjacent to each other, and may be a part ranging from the front surface of the semiconductor substrate 10 to a depth of a deepest bottom portion of each trench portion. The extension portions of each trench portion may be regarded as one trench portion. That is, the region sandwiched between two extension portions may be set to be a mesa portion.

The mesa portion 71 is provided adjacent to at least one of the dummy trench portion 30 or the gate trench portion 40 in the transistor portion 70. The mesa portion 71 has the well region 17, the emitter region 12, the base region 14, and the contact region 15, in the front surface of the semiconductor substrate 10. The mesa portion 71 includes the emitter regions 12 and the contact regions 15 alternately provided in the extension direction.

The mesa portion 91 is provided in the mixed portion 90. In the area illustrated in FIG. 2, as in the mesa portion 71, the mesa portion 91 has the well region 17, the base region 14, and the emitter region 12 and the contact region 15, which are alternately provided in the extension direction, on the front surface of the semiconductor substrate 10.

The mesa portion 81 is provided in a region interposed between the dummy trench portions 30 adjacent to each other in the diode portion 80. The mesa portion 81 in the present example has the base region 14 and has the well region 17 on the negative side in the Y axis direction, in the front surface of the semiconductor substrate 10. In the mesa portion 81, the contact region 15 similar to that of the mixed portion 90 may be provided on the front surface of the base region 14.

The base region 14 is a region provided on the front surface side of the semiconductor substrate 10 in the transistor portion 70 and the diode portion 80. The base region 14 is of the P-type as an example. The base region 14 may be provided at both ends of the mesa portion 71 and the mesa portion 91 in the Y axis direction, on the front surface of the semiconductor substrate 10. Note that FIG. 2 only illustrates the end of the base region 14 on the negative side in the Y axis direction.

The emitter region 12 is of the same conductivity type as that of the drift region 18 and has a higher doping concentration than the drift region 18. The emitter region 12 in the present example is of the N+ type as an example. An example of a dopant of the emitter region 12 is arsenic (As). The emitter region 12 is provided in contact with the gate trench portion 40 at the front surface of the mesa portion 71. The emitter region 12 may be provided to extend in the X axis direction from one of two trench portions sandwiching the mesa portion 71 to the other of the two trench portions. The emitter region 12 is also provided below the contact hole 54.

In addition, the emitter region 12 may or may not be in contact with the dummy trench portion 30. The emitter region 12 in the present example is in contact with the dummy trench portion 30. The emitter region 12 may not be provided in the mesa portion 81 and the mesa portion 91.

The contact region 15 is a region of the same conductivity type as that of the base region 14 and has a higher doping concentration than the base region 14. The contact region 15 in the present example is of the P+ type as an example. The contact region 15 of the present example is provided on the front surfaces of the mesa portion 71 and the mesa portion 91. The contact region 15 may be provided from one trench portion to another trench portion of two trench portions which interpose the mesa portion 71 or the mesa portion 91 therebetween in the X axis direction. The contact region 15 may be or may not be in contact with the gate trench portion 40. Moreover, the contact region 15 may be or may not be in contact with the dummy trench portion 30. In the present example, the contact region 15 is in contact with the dummy trench portion 30 and the gate trench portion 40. The contact region 15 is also provided below the contact hole 54.

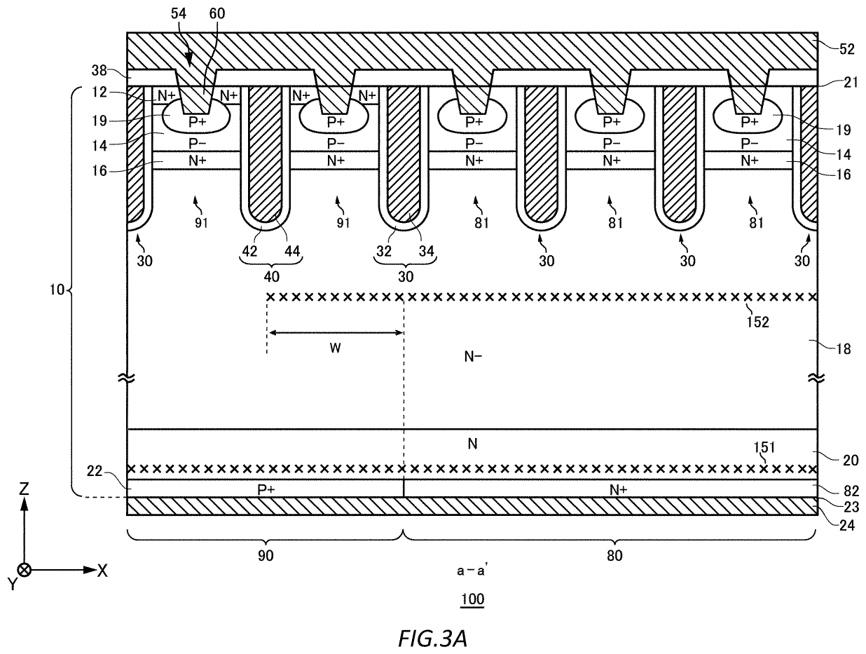

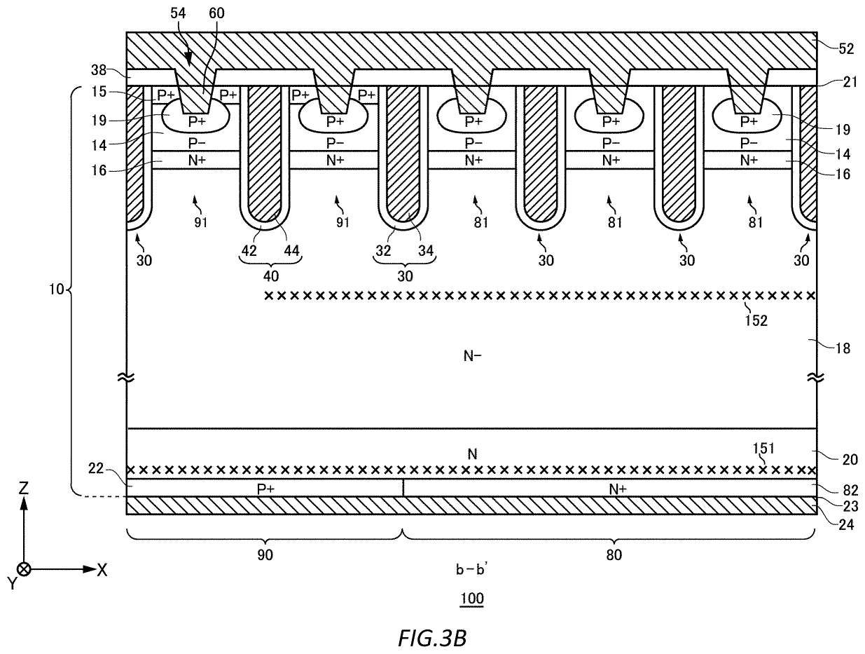

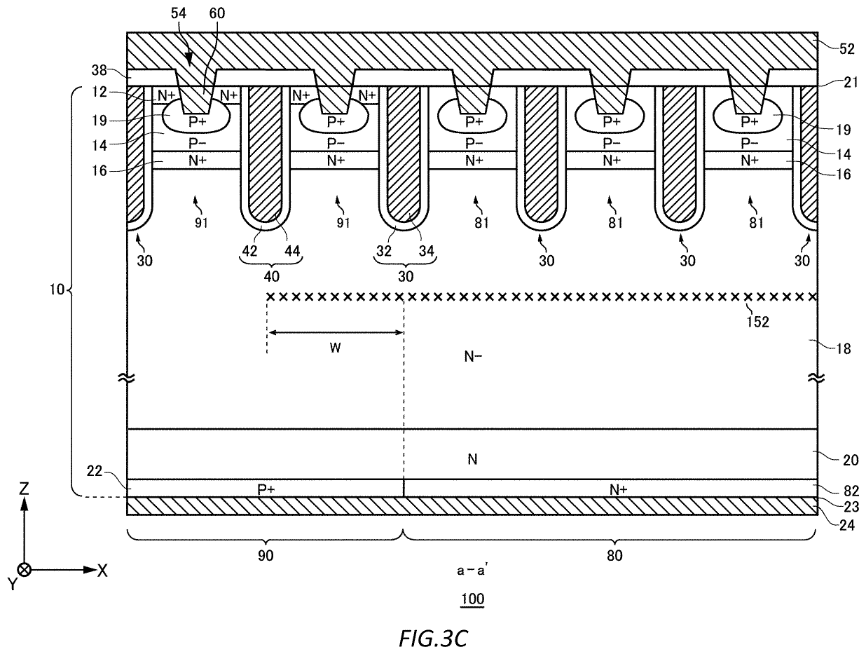

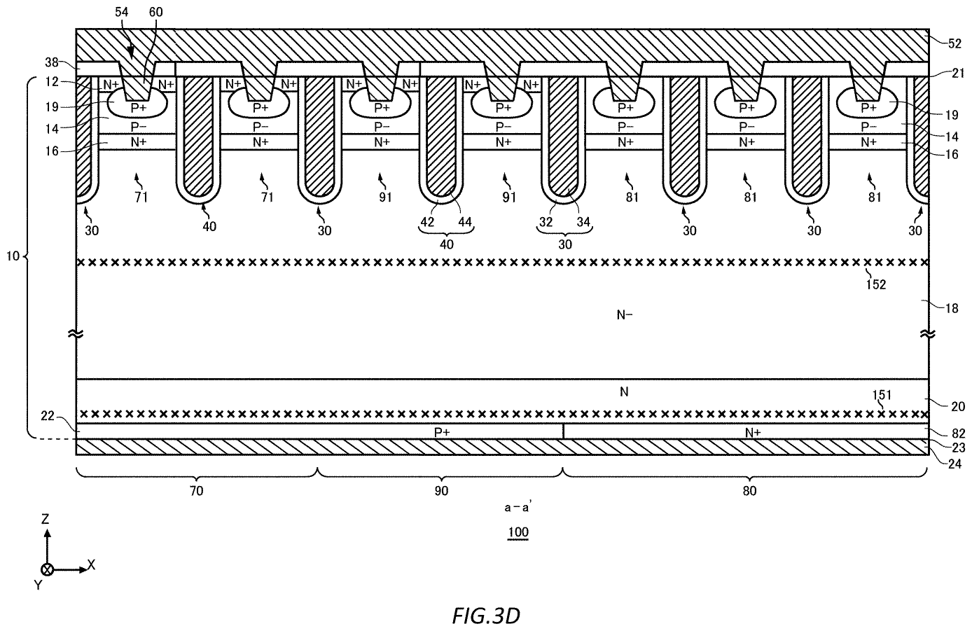

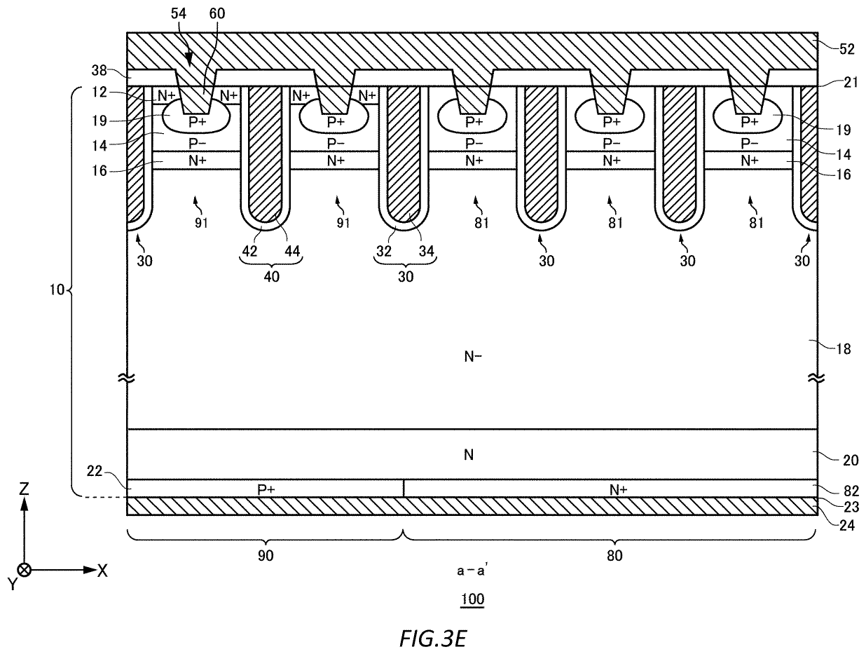

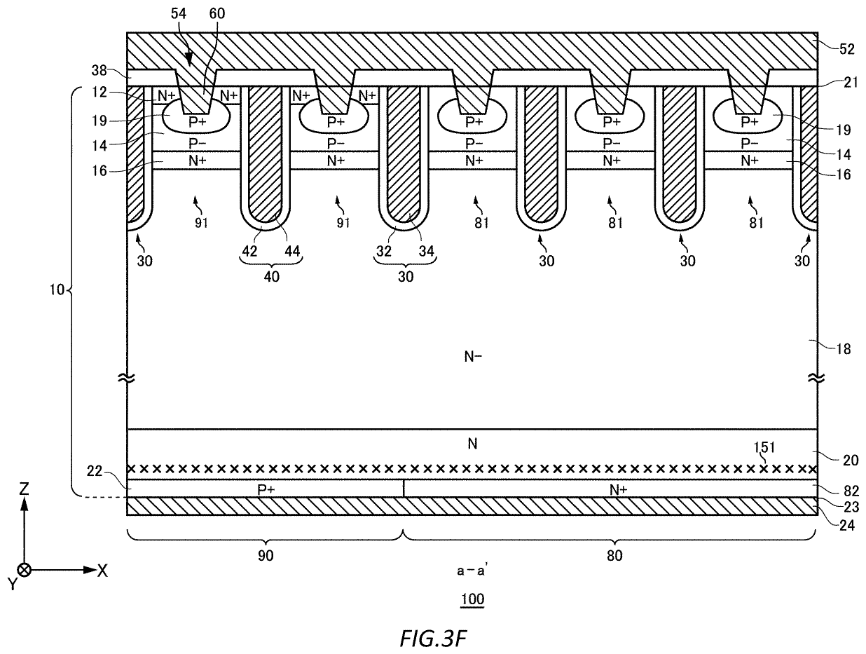

FIG. 3A is a diagram which illustrates an example of a cross section a-a′ in FIG. 2. The a-a′ cross section is the XZ plane which passes through the emitter region 12 in the mixed portion 90. In the cross section a-a′, the semiconductor device 100 in the present example has the semiconductor substrate 10, the interlayer dielectric film 38, the emitter electrode 52, and a collector electrode 24. The emitter electrode 52 is provided above the semiconductor substrate 10 and the interlayer dielectric film 38. It is noted that, although the a-a′ cross section does not pass through the transistor portion 70, the transistor portion 70 has approximately the same structure as the mixed portion 90 on the same XZ plane and thus is not illustrated.

The drift region 18 is provided in the semiconductor substrate 10. The drift region 18 in the present example is of the N-type as an example. The drift region 18 may be a region which has remained without other doping regions formed in the semiconductor substrate 10. That is, the doping concentration of the drift region 18 may be a doping concentration of the semiconductor substrate 10.

A buffer region 20 is provided below the drift region 18. The buffer region 20 in the present example is of the same conductivity type as that of the drift region 18, and is of N type as an example. The doping concentration in the buffer region 20 is higher than the doping concentration in the drift region 18. The buffer region 20 may serve as a field stop layer which prevents a depletion layer expanding from the lower surface side of the base region 14 from reaching the collector region 22 and the cathode region 82.

The collector region 22 is a region which is provided below the buffer region 20 in the transistor portion 70 and which is of a conductivity type different from that of the drift region 18. The cathode region 82 is a region which is provided below the buffer region 20 in the diode portion 80 and which is of the same conductivity type as that of the drift region 18.

The collector electrode 24 is provided on the back surface 23 of the semiconductor substrate 10. The collector electrode 24 is formed of a conductive material such as metal.

The base region 14 is a region which is of a conductivity type different from that of the drift region 18 and is provided above the drift region 18 in the mesa portion 71, the mesa portion 81, and the mesa portion 91. The base region 14 in the present example is of the P-type as an example. The base region 14 is provided in contact with the gate trench portion 40. The base region 14 may be provided in contact with the dummy trench portion 30.

The emitter region 12 is provided between the base region 14 and the front surface 21 of the semiconductor substrate 10. The emitter region 12 in the present example is provided in the mesa portion 71 and the mesa portion 91, but is not provided in the mesa portion 81. The emitter region 12 is provided in contact with the gate trench portion 40. The emitter region 12 may be or may not be in contact with the dummy trench portion 30.

The contact region 15 is provided above the base region 14 in the mesa portion 71 and the mesa portion 91. The contact region 15 is provided in contact with the dummy trench portion 30, in the mesa portion 71 and the mesa portion 91. In another cross section, the contact region 15 may be provided on the front surface of the mesa portion 71 and the mesa portion 91.

The contact trench portion 60 includes a conductive material filled within the contact hole 54. The contact trench portion 60 is provided between two adjacent trench portions among the plurality of trench portions. The contact trench portion 60 in the present example is provided to penetrate through the emitter region 12 from the front surface 21 and is in contact with the plug region 19 on the bottom surface. The contact trench portion 60 may include the same material as the emitter electrode 52. In addition, the contact trench portion 60 may have a plug with barrier metal incorporated therebetween.

The lower end of the contact trench portion 60 may be deeper than or shallower than the lower end of the emitter region 12. Providing the contact trench portion 60 can reduce the resistance of the base region 14 and facilitate minority carriers (for example, holes) to be extracted. This can improve the destructive breakdown withstand capability such as a latch-up withstand capability due to minority carriers.

The contact trench portion 60 includes a bottom surface of a substantially planar shape. The bottom surface of the contact trench portion 60 is covered by the plug region 19. The contact trench portion 60 of the present example has a tapered shape with angled side walls. However, the side walls of the contact trench portion 60 may be provided to be substantially perpendicular to the front surface 21.

The plug region 19 is provided below the contact trench portion 60. The plug region 19 is a region which is of the same conductivity type as that of the base region 14 and has a higher doping concentration than that of the base region 14. The plug region 19 of the present example is of P+ type, as an example. For example, the plug region 19 is formed as a result of ion implantation of boron (B) or boron fluoride (BF₂). The plug region 19 may have the same doping concentration as that of the contact region 15. The plug region 19 prevents a latch-up by extracting minority carriers.

The plug region 19 may be provided on the side wall and the bottom surface of the contact trench portion 60. The plug region 19 of the present example may be provided in each of the mesa portion 71, the mesa portion 81, and the mesa portion 91. The plug region 19 may be provided to extend in the Y axis direction.

The accumulation region 16 is a region provided above the drift region 18. The accumulation region 16 of the present example is a region which is of the same conductivity type as the drift region 18 and has a higher doping concentration than that of the drift region 18. The accumulation region 16 in the present example is of the N+ type as an example. The accumulation region 16 of the present example is provided in each of the transistor portion 70, the mixed portion 90, and the diode portion 80. However, the accumulation region 16 may be provided only in the transistor portion 70 and may not be provided in the mixed portion 90 and the diode portion 80. Alternatively, the accumulation region 16 may be provided in the transistor portion 70 and the mixed portion 90, and may not be provided in the diode portion 80.

The accumulation region 16 of the present example is provided to be in contact with the gate trench portion 40. The accumulation region 16 may be or may not be in contact with the dummy trench portion 30. Providing the accumulation region 16 can enhance the carrier implantation enhancement effect (IE effect) to reduce an ON voltage of the transistor portion 70.

One or more gate trench portions 40 and one or more dummy trench portions 30 are provided in the front surface 21 of the semiconductor substrate 10. Each trench portion is provided from the front surface 21 of the semiconductor substrate 10 to the drift region 18. In the regions where at least any of the emitter region 12, the base region 14, the contact region 15, or the accumulation region 16 is provided, each trench portion penetrates through these regions to reach the drift region 18. The configuration of the trench portion penetrating the doping region is not limited to the one manufactured in the order of forming the doping region and then forming the trench portion. A configuration where the doping region formed between the trench portions after the formation of the trench portion may also be included in the configuration where the trench portion penetrates the doping region.

The gate trench portion 40 has a gate trench, a gate dielectric film 42, and a gate conductive portion 44 that are formed in the front surface 21 of the semiconductor substrate 10. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 inside the gate trench. The gate dielectric film 42 insulates the gate conductive portion 44 from the semiconductor substrate 10. The gate conductive portion 44 may be formed of a conductive material such as polysilicon. The gate trench portion 40 is covered by the interlayer dielectric film 38 at the front surface 21 of the semiconductor substrate 10.

The gate conductive portion 44 includes a region opposing the adjacent base region 14 in the mesa portion 71 side by sandwiching the gate dielectric film 42 in a depth direction of the semiconductor substrate 10. When a predetermined voltage is applied to the gate conductive portion 44, a channel due to an electron inversion layer is formed in a surface layer of the boundary in direct contact with the gate trench among the base region 14.

The dummy trench portion 30 may have the same structure as the gate trench portion 40. The dummy trench portion 30 has a dummy trench, a dummy dielectric film 32, and a dummy conductive portion 34 formed on the front surface 21 of the semiconductor substrate 10. The dummy dielectric film 32 is provided to cover an inner wall of the dummy trench. The dummy conductive portion 34 is formed inside the dummy trench and is provided on the inner side of the dummy dielectric film 32. The dummy dielectric film 32 insulates the dummy conductive portion 34 from the semiconductor substrate 10. The dummy trench portion 30 is covered by the interlayer dielectric film 38 on the front surface 21 of the semiconductor substrate 10.

The interlayer dielectric film 38 is provided on the front surface 21 of the semiconductor substrate 10. The emitter electrode 52 is provided above the interlayer dielectric film 38. The interlayer dielectric film 38 is provided with one or more contact holes 54 to electrically connect the emitter electrode 52 and the semiconductor substrate 10. Similarly, the contact hole 55 and the contact hole 56 may be provided to penetrate through the interlayer dielectric film 38.

The semiconductor device 100 of the present example comprises a back surface side lifetime control region 151 and a front surface side lifetime control region 152. It should be noted that the semiconductor device 100 may not include one of the back surface side lifetime control region 151 or the front surface side lifetime control region 152.

The back surface side lifetime control region 151 and the front surface side lifetime control region 152 are regions where a lifetime killer is intentionally formed by a method such as implanting impurity into the semiconductor substrate 10. The lifetime killer is a recombination center for a carrier. The lifetime killer may be a lattice defect. For example, the lifetime killer may be a vacancy, a divacancy, a defect complex of these with elements constituting the semiconductor substrate 10, or a dislocation. Furthermore, the lifetime killer may be a noble gas element such as helium and neon, a metal element such as platinum, or the like. An electron beam or a proton may be used for forming the lattice defect. Providing the back surface side lifetime control region 151 and the front surface side lifetime control region 152 can reduce the turn-off time, and suppressing tail current can reduce the loss upon switching.

The back surface side lifetime control region 151 is provided on the back surface 23 side with respect to the center of the semiconductor substrate 10 in the depth direction of the semiconductor substrate 10. The back surface side lifetime control region 151 of the present example is provided in the buffer region 20. The back surface side lifetime control region 151 of the present example is provided on the entire surface of the semiconductor substrate 10 in the XY plane, and can be formed without using a mask.

The back surface side lifetime control region 151 may be formed by implantation from the back surface 23 side of the semiconductor substrate 10. In this way, the impact on the front surface 21 side of the semiconductor device 100 can be suppressed. For example, the back surface side lifetime control region 151 is formed by being irradiated with helium or proton from the back surface 23 side of the semiconductor device 100. Whether the back surface side lifetime control region 151 is formed by implantation from the front surface 21 side or the back surface 23 side of the semiconductor device 100 can be determined by obtaining the state of the front surface 21 side of the semiconductor device 100 through the SRP method or leak current measurement.

The front surface side lifetime control region 152 is provided on the front surface 21 side with respect to the center of the semiconductor substrate 10 in the depth direction of the semiconductor substrate 10. The front surface side lifetime control region 152 in the present example is provided in a drift region 18. The front surface side lifetime control region 152 of the present example is provided to extend from the end of the diode portion 80 side of the mixed portion 90 by a distance W in the X axis direction toward the transistor portion 70. The extension distance W may be 0 μm or more and 360 μm or less, or may be 2.0 μm or more and 360 μm or less. It is noted that the lower limit value of the extension distance W may be the width of a single mesa portion 91.

In the X axis direction, the front surface side lifetime control region 152 extending from the diode portion 80 may extend through the mixed portion 90 to a part of the transistor portion 70 or may terminate within the mixed portion 90 without reaching the transistor portion 70. Providing the front surface side lifetime control region 152 can suppress the implantation of holes and reduce reverse recovery loss.

The front surface side lifetime control region 152 may be formed by irradiating the semiconductor substrate 10 from the front surface 21. The front surface side lifetime control region 152 may alternatively be formed by irradiation from the back surface 23 side of the semiconductor substrate 10. The element, dose amount, or the like for forming the back surface side lifetime control region 151 and the front surface side lifetime control region 152 may be the same or may be different.

The front surface side lifetime control region 152 may be provided below the gate trench portion 40. When a particle beam or the like for forming the front surface side lifetime control region 152 passes through the MOS gate structure of the semiconductor device 100, a defect may occur at the interface between the gate oxide film and the semiconductor substrate, causing the threshold voltage to fluctuate. However, setting the extension distance W from the diode portion 80 to the above-described range can suppress the fluctuation of the threshold voltage.

FIG. 3B is a diagram which illustrates an example of a cross section b-b′ in FIG. 2. The cross section b-b′ is the XZ plane which passes through the contact region 15 in the transistor portion 70. It is noted that, although the b-b′ cross section, like the a-a′ cross section, does not pass through the transistor portion 70, the transistor portion 70 has approximately the same structure as the mixed portion 90 on the same XZ plane and thus is not illustrated.

The mesa portion 71 and the mesa portion 91 have a base region 14, a contact region 15, an accumulation region 16, and a plug region 19 in the b-b′ cross section. As in the case of the a-a′ cross section, the mesa portion 91 has a contact region 15, an accumulation region 16, and a plug region 19. In the cross section b-b′, the mesa portion 71 has the same structure as the mesa portion 91. The mesa portion 81 has the base region 14, the accumulation region 16, and the plug region 19, similarly to the cross section a-a′.

FIG. 3C is a diagram which illustrates another example of the a-a′ cross section in FIG. 2. The a-a′ cross section is the XZ plane which passes through the emitter region 12 in the mixed portion 90. In the cross section a-a′, the semiconductor device 100 in the present example has the semiconductor substrate 10, the interlayer dielectric film 38, the emitter electrode 52, and the collector electrode 24. The emitter electrode 52 is provided above the semiconductor substrate 10 and the interlayer dielectric film 38. It is noted that, although the a-a′ cross section does not pass through the transistor portion 70, the transistor portion 70 has approximately the same structure as the mixed portion 90 on the same XZ plane and thus is not illustrated.

FIG. 3C is different from FIG. 3A in that the back surface side lifetime control region 151 is not provided. The back surface side lifetime control region 151 may not be provided depending on the doping concentration of the buffer region 20 or the application of the semiconductor device 100.

FIG. 3D is a diagram which illustrates another example of a cross section a-a′ in FIG. 2. The a-a′ cross section is the XZ plane which passes through the emitter region 12 in the mixed portion 90. In the cross section a-a′, the semiconductor device 100 in the present example has the semiconductor substrate 10, the interlayer dielectric film 38, the emitter electrode 52, and the collector electrode 24. The emitter electrode 52 is provided above the semiconductor substrate 10 and the interlayer dielectric film 38.

FIG. 3D is different from FIG. 3A in that the front surface side lifetime control region 152 is provided on the entire surface. In addition, the semiconductor device 100 of the present example is not provided with the extension distance W. Like the back surface side lifetime control region 151, the front surface side lifetime control region 152 may be formed by implantation from the back surface 23 side of the semiconductor substrate 10. In this way, the impact on the front surface 21 side of the semiconductor device 100 can be suppressed. For example, the front surface side lifetime control region 152 is formed by being irradiated with helium or proton from the back surface 23 side of the semiconductor device 100. The front surface side lifetime control region 152 of the present example is provided on the entire surface of the semiconductor substrate 10 in the XY plane, and can be formed without using a mask.

FIG. 3E is a diagram which illustrates another example of the cross section a-a′ in FIG. 2. The a-a′ cross section is the XZ plane which passes through the emitter region 12 in the mixed portion 90. In the cross section a-a′, the semiconductor device 100 in the present example has the semiconductor substrate 10, the interlayer dielectric film 38, the emitter electrode 52, and the collector electrode 24. The emitter electrode 52 is provided above the semiconductor substrate 10 and the interlayer dielectric film 38. It is noted that, although the a-a′ cross section does not pass through the transistor portion 70, the transistor portion 70 has approximately the same structure as the mixed portion 90 on the same XZ plane and thus is not illustrated.

FIG. 3E is different from FIG. 3A in that it is not provided with the back surface side lifetime control region 151 and the front surface side lifetime control region 152. The back surface side lifetime control region 151 and the front surface side lifetime control region 152 may not be provided, depending on the doping concentration of the buffer region 20 or the application of the semiconductor device 100.

FIG. 3F is a diagram which illustrates another example of a cross section a-a′ in FIG. 2. The a-a′ cross section is the XZ plane which passes through the emitter region 12 in the mixed portion 90. In the cross section a-a′, the semiconductor device 100 in the present example has the semiconductor substrate 10, the interlayer dielectric film 38, the emitter electrode 52, and the collector electrode 24. The emitter electrode 52 is provided above the semiconductor substrate 10 and the interlayer dielectric film 38. It is noted that, although the a-a′ cross section does not pass through the transistor portion 70, the transistor portion 70 has approximately the same structure as the mixed portion 90 on the same XZ plane and thus is not illustrated.

FIG. 3F is different from FIG. 3A in that the front surface side lifetime control region 152 is not provided. The front surface side lifetime control region 152 may not be provided depending on the doping concentration of the buffer region 20 or the application of the semiconductor device 100.

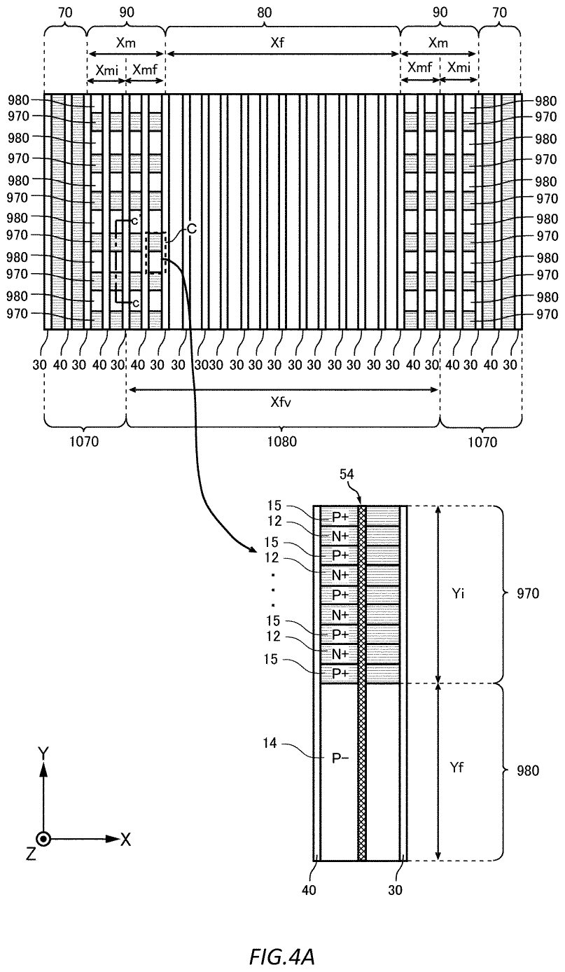

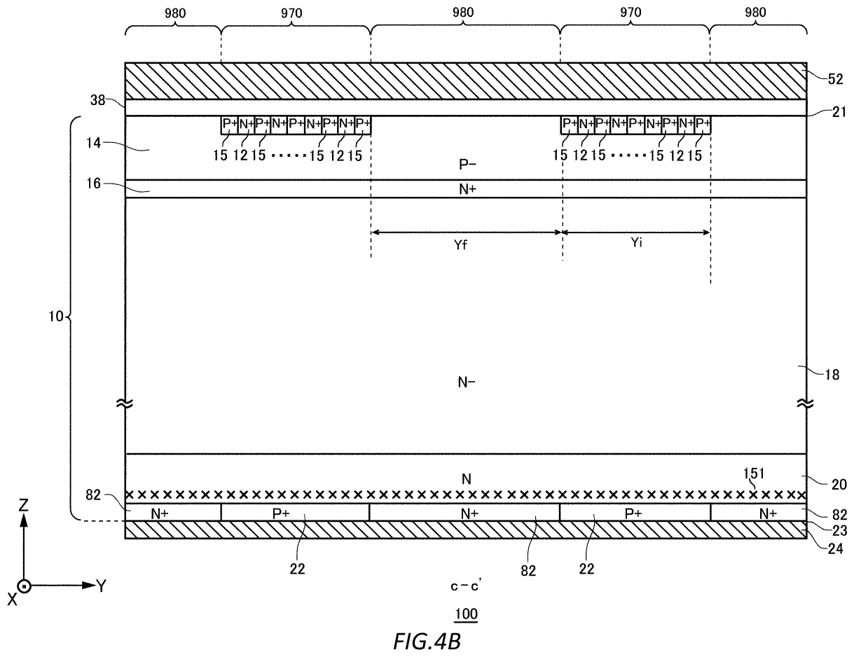

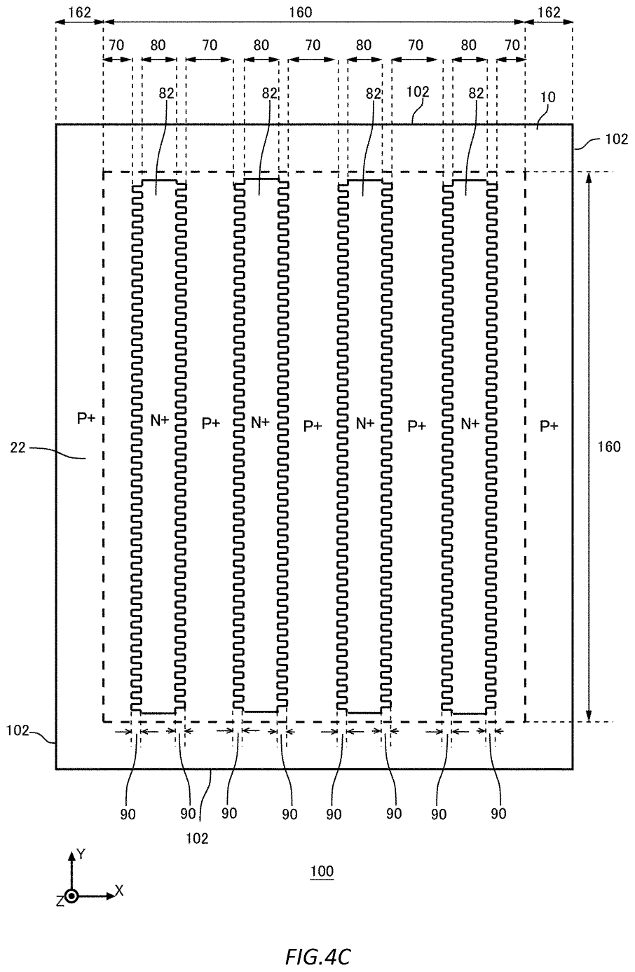

FIG. 4A is an enlarged view which illustrates an example of the region B in FIG. 1. The region B is a region spanning the mixed portion 90 and a part of the transistor portion 70 with the diode portion 80 as the center at the edge side on the negative side in the Y axis direction of the semiconductor device 100 in the top view. FIG. 4A further illustrates an enlarged view of the region C of the mesa portion 91 of the mixed portion 90.

The mixed portion 90 is a region where a transistor region 970, below which the collector region 22 is provided, and a diode region 980, below which the cathode region 82 is provided, are alternately provided in the Y axis direction. The mixed portion 90 is provided between the transistor portion 70 and the diode portion 80. The mixed portion 90 has the gate trench portion 40 and the dummy trench portion 30. The ratio of the gate trench portion 40 to the dummy trench portion 30 in the mixed portion 90 may be similar to that of the transistor portion 70. The contact hole 54 is provided above the mesa portion 91 of the mixed portion 90.

The transistor region 970 has the emitter region 12 and the contact region 15, which are provided alternately in the Y axis direction, on the front surface of the mesa portion 91. That is, the front surface structure of the transistor region 970 is the same as the front surface structure of the transistor portion 70. In FIG. 4A, the transistor portion 70 and the transistor region 970 of the mixed portion 90, that is, a region acting as a transistor, are hatched.

The diode region 980 is adjacent to the transistor region 970 in the Y axis direction as illustrated in the enlarged view of the region C. The diode region 980 has the base region 14 provided on the front surface 21 of the semiconductor substrate 10. That is, the front surface structure of the diode region 980 is the same as the front surface structure of the diode portion 80.

In the semiconductor device 100 of the present example, the region acting as a transistor (the hatched region) and the region acting as a diode constitute a serrated boundary in the mixed portion 90.

The RC-IGBT suppresses the change in temperature by having both the transistor and the diode share the heat generated during continuous operation or a short circuit. During continuous operation, it suppresses the change in temperature by diffusing the heat to the diode during the operation of the transistor or to the transistor during the operation of the diode. At this time, the heat is exchanged through the boundary between the transistor and the diode. The heat which is suddenly generated in the transistor during a short circuit is diffused to the diode so that the short circuit withstand capability can improve.

According to the semiconductor device 100 of the present example, since the region acting as a transistor and the region acting as a diode constitute the serrated boundary in the mixed portion 90, the extension distance of the boundary is greater than in the case where the boundary between the transistor and the diode is a straight line. In this way, the heat diffusion is facilitated and the short circuit withstand capability is improved. The improved short circuit withstand capability can increase the saturation current, which can reduce the turn-on loss as a result.

In the X axis direction, the width Xm of the mixed portion 90 may be 50 μm or more and 200 μm or less. The width Xm of the mixed portion 90 may be smaller than the width of the transistor portion 70 and may be smaller than the width Xf of the diode portion.

In the Y axis direction, the length Yi of the transistor region 970 in the mixed portion 90 may be 5 μm or more and 250 μm or less. In the example of FIG. 4A, the ratio of the length Yi of the transistor region 970 in the mixed portion 90 to the length Yf of the diode region 980 in the Y axis direction is 1:1.

The region adjacent to the diode portion 80 in the mixed portion 90 is defined as a diode portion side mixed region, and the region adjacent to the transistor portion 70 is defined as a transistor portion side mixed region. The area including the diode portion 80 and the diode portion side mixed regions added to both ends thereof in the X axis direction is defined as a virtual diode portion 1080, and the area including the transistor portion 70 and the transistor portion side mixed regions added to both ends thereof is defined as a virtual transistor portion 1070. That is, the virtual diode portion 1080 and the virtual transistor portion 1070 correspond to the diode portion and the transistor portion which are not provided with the mixed portion 90, respectively.

In the X axis direction, the width Xfv of the virtual diode portion 1080, the width Xf of the diode portion, and the width Xmf of the diode portion side mixed region meet the following relationship:

$$Xfv = Xf + 2 Xmf .$$

In the X axis direction, the width Xm of the mixed portion 90 may be 4.6 μm or more and equal to or less than the width Xfv of the virtual diode portion 1080.

The ratio of the total area of the transistor regions 970 and the total area of the diode regions 980 in the mixed portion 90 is determined based on the ratio of the width Xmi of the transistor portion side mixed region to the width Xmf of the diode portion side mixed region in the X axis direction and the ratio of the length Yi of the transistor region 970 to the length Yf of the diode region 980 in the Y axis direction. Therefore, when the ratio of the width Xmi of the transistor portion side mixed region to the width Xmf of the diode portion side mixed region is equal to the ratio of the length Yi of the transistor region 970 to the length Yf of the diode region 980, that is, when

$$Xmi : Xm = Yi : Yf$$

is met, the total area of the transistor regions 970 is equal to the area of the transistor portion side mixed region, and the total area of the diode regions 980 is equal to the area of the diode portion side mixed region.

In this case, the area of the region acting as a transistor, that is, the sum of the area of the transistor portion 70 and the total area of the transistor regions 970 is equal to the area of the virtual transistor portion 1070, and the area of the region acting as a diode, that is, the sum of the area of the diode portion 80 and the total area of the diode region 980 is equal to the area of the virtual diode portion 1080. In this way, by providing the mixed portion 90, the heat diffusion is facilitated and the short circuit withstand capability is improved, while maintaining the characteristics of the transistor portion 70 and the diode portion 80 which are not provided with the mixed portion 90. The improved short circuit withstand capability can increase the saturation current, which can reduce the turn-on loss as a result.

As shown in FIG. 4A, when the ratio of the length Yi of the transistor region 970 to the length Yf of the diode region 980 in the Y axis direction is 1:1, the ratio of the width Xmi of the transistor portion side mixed region to the width Xmf of the diode portion side mixed region may be 1:1 in the X axis direction.

FIG. 4B is a diagram which illustrates an example of the c-c′ cross section in FIG. 4A. The c-c′ cross section is the YZ plane passing through the mesa portion 91. In the transistor region 970, the collector region 22 is provided on the back surface 23 of the semiconductor substrate 10. In the diode region 980, the cathode region 82 is provided on the back surface 23 of the semiconductor substrate 10.

FIG. 4C illustrates an example of the arrangement of the collector region 22 and the cathode region 82. FIG. 4C is the top view of the semiconductor device 100, but, for convenience, the members above the collector region 22 and the cathode region 82 are omitted.

In the transistor portion 70, the collector region 22 is provided on the back surface 23 of the semiconductor substrate 10. In the diode portion 80, the cathode region 82 is provided on the back surface 23 of the semiconductor substrate 10. In the edge termination structure portion 162, the collector region 22 may be provided on the back surface 23 of the semiconductor substrate 10.

In the mixed portion 90, the collector region 22 corresponding to the transistor region 970 and the cathode region 82 corresponding to the diode region 980 are alternately provided in the Y axis direction. As a result, the collector region 22 corresponding to the transistor portion 70 and the transistor region 970 of the mixed portion 90, and the cathode region 82 corresponding to the diode portion 80 and the diode region 980 of the mixed portion 90 constitute the serrated boundary in the mixed portion 90.

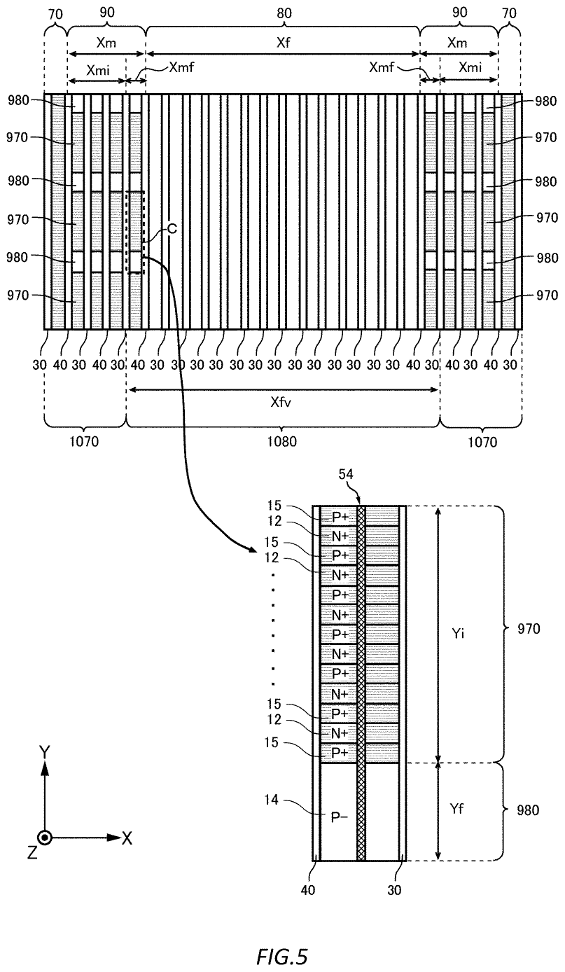

FIG. 5 is an enlarged view which illustrates another example of the region B in FIG. 1. In the example of FIG. 5, the length Yi of the transistor region 970 in the mixed portion 90 is greater than the length Yf of the diode region 980 in the Y axis direction, and the width Xmi of the transistor portion side mixed region is greater than the width Xmf of the diode portion side mixed region in the X axis direction.

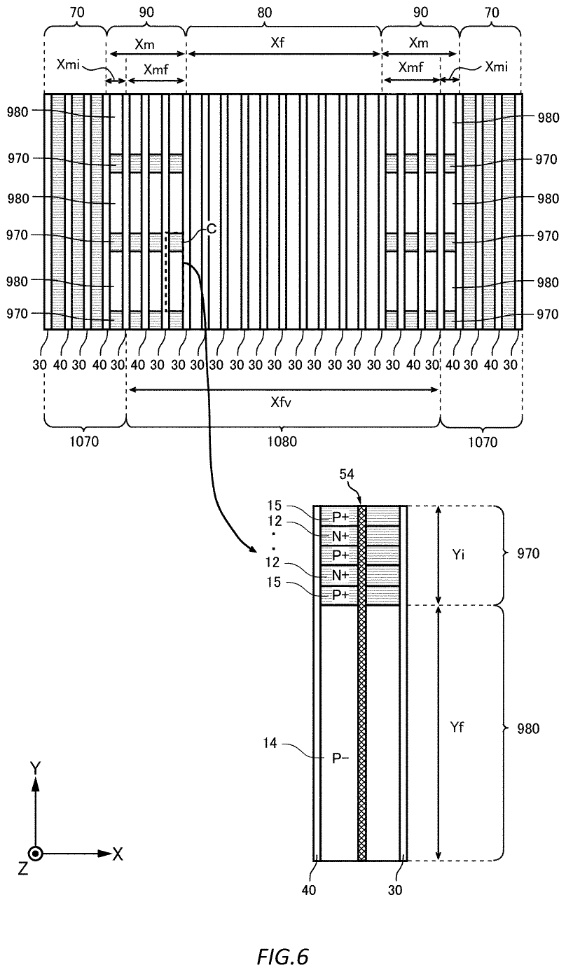

FIG. 6 is an enlarged view which illustrates yet another example of the region B in FIG. 1. In the example of FIG. 6, the length Yi of the transistor region 970 in the mixed portion 90 is smaller than the length Yf of the diode region 980 in the Y axis direction, and the width Xmi of the transistor portion side mixed region is smaller than the width Xmf of the diode portion side mixed region in the X axis direction.

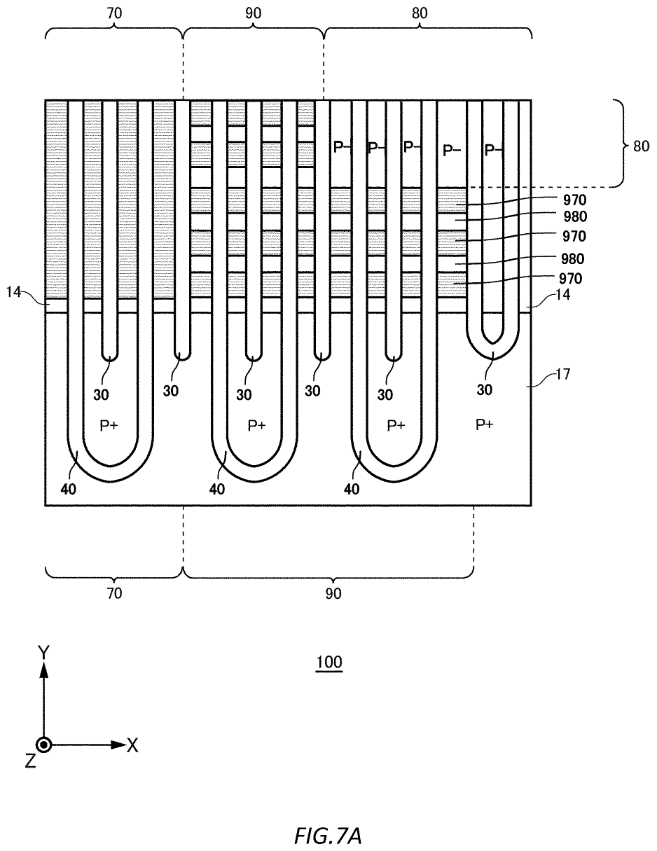

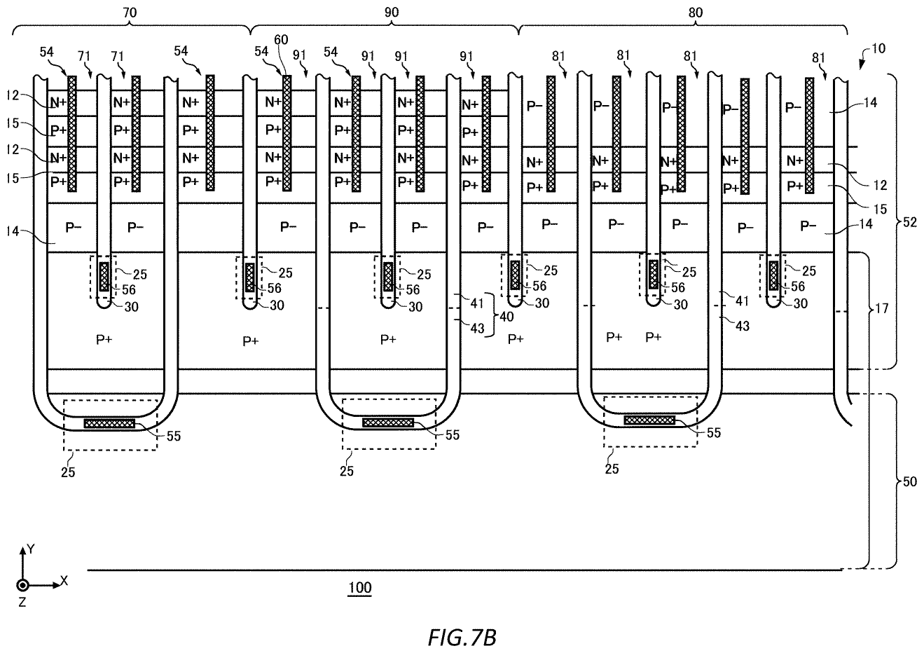

FIG. 7A is an enlarged view which illustrates another example of the region A in FIG. 1. In the Y axis direction, the mixed portion 90 of the present example is also provided between the end of the diode portion 80 and the edge termination structure portion 162.

The diode portion 80 of the present example differs from the examples of FIG. 1 to FIG. 6 in that it has the gate trench portion 40. The gate trench portion 40 in the diode portion 80 is provided to extend from the diode portion 80 to the mixed portion 90.

The region between the end of the diode portion 80 and the edge termination structure portion 162 may be referred to as an extension region of the diode portion 80. In the vicinity of the end of the diode portion 80, the electric field intensity is highest during reverse recovery operation and also current is concentrated. Therefore, in the extension region, the back surface of the semiconductor substrate 10 is not provided with the cathode region 82 but is provided with the collector region 22 instead. Preventing the extension region from acting act as a diode can suppress the current concentration during reverse recovery and increase the current withstand capability during reverse recovery.

In the semiconductor device 100 of the present example, the mixed portion 90 is expanded to the extension region of the diode portion 80 and the gate trench portion 40 is provided to extend from the diode portion 80 to the mixed portion 90, which causes the invalid region not acting as a diode to act as a transistor, and facilitates heat diffusion as in FIG. 1 to FIG. 6, improving short circuit withstand capability. The improved short circuit withstand capability can increase the saturation current, which can reduce the turn-on loss as a result.

FIG. 7B is an enlarged view which illustrates yet another example of the region A in FIG. 1. In the Y axis direction, the semiconductor device 100 of the present example has the emitter region 12 and the contact region 15, which are alternately provided, between the end of the diode portion 80 and the edge termination structure portion 162. The diode portion 80 of the present example has the gate trench portion 40. The gate trench portion 40 in the diode portion 80 is provided to extend from the diode portion 80 to the mixed portion 90.

In other words, in the semiconductor device 100 of the present example, the transistor region 970 is provided in the extension region of the diode portion 80. This can cause the invalid region not acting as a diode to act as a transistor, increasing the active area.

While the embodiments of the present invention have been described, the technical scope of the present invention is not limited to the above-described embodiments. It is apparent to persons skilled in the art that various alterations or improvements can be added to the above-described embodiments. It is also apparent from the described scope of the claims that the embodiments added with such alterations or improvements can be included the technical scope of the present invention.

Note that the operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10 semiconductor substrate,
12 emitter region,
14 base region,
15 contact region,
16 accumulation region,
17 well region,
18 drift region,
19 plug region,
20 buffer region,
21 front surface,
22 collector region,
23 back surface,
24 collector electrode,
25 connecting portion,
30 dummy trench portion,
31 extension portion,
32 dummy dielectric film,
33 connecting portion,
34 dummy conductive portion,
38 interlayer dielectric film,
40 gate trench portion,
41 extension portion,
42 gate dielectric film,
43 connecting portion,
44 gate conductive portion,
50 gate metal layer,
52 emitter electrode,
54 contact hole,
55 contact hole,
56 contact hole,
60 contact trench portion,
70 transistor portion,
71 mesa portion,
80 diode portion,
81 mesa portion,
82 cathode region,
90 mixed portion,
91 mesa portion,
100 semiconductor device,
102 end side,
151 back surface side lifetime control region,
152 front surface side lifetime control region,
160 active region,
162 edge termination structure portion,
970 transistor region,
980 diode region,
1070 virtual transistor portion,
1080 virtual diode portion.

What is claimed is:

1. A semiconductor device comprising a transistor portion and a diode portion, having:
a drift region of a first conductivity type which is provided in a semiconductor substrate;
a plurality of trench portions which extends in a predetermined trench extension direction on a front surface side of the semiconductor substrate;
a base region of a second conductivity type which is provided above the drift region;
an emitter region of the first conductivity type which is provided on the front surface of the semiconductor substrate and has a higher doping concentration than that of the drift region;
a contact region of the second conductivity type which is provided above the drift region and has a higher doping concentration than that of the base region;
a cathode region of the first conductivity type which is provided on a back surface of the semiconductor substrate and has a higher doping concentration than that of the drift region; and
a collector region of the second conductivity type which is provided on the back surface of the semiconductor substrate and has a higher doping concentration than that of the base region,
comprising a mixed portion where a transistor region below which the collector region is provided and a diode region below which the cathode region is provided are alternately provided in the trench extension direction.

2. The semiconductor device according to claim 1, wherein the mixed portion is provided between the transistor portion and the diode portion.

3. The semiconductor device according to claim 1, wherein a width of the mixed portion is smaller than a width of the transistor portion in a trench arrangement direction.

4. The semiconductor device according to claim 1, wherein a width of the mixed portion is smaller than a width of the diode portion in a trench arrangement direction.

5. The semiconductor device according to claim 1, wherein a length of the transistor region in the mixed portion is 5 μm or more and 250 μm or less in the trench extension direction.

6. The semiconductor device according to claim 2, wherein the mixed portion has a diode portion side mixed region adjacent to the diode portion and a transistor portion side mixed region adjacent to the transistor portion, and
in a trench arrangement direction, a width of the mixed portion is 4.6 μm or more and equal to or less than a width of a virtual diode portion including the diode portion and the diode portion side mixed region added to both ends thereof.

7. The semiconductor device according to claim 6, wherein when, in the trench extension direction, a ratio of a length of the transistor region to a length of the diode region in the mixed portion is 1:1, in a trench arrangement direction, a ratio of a width of the transistor portion side mixed region to a width of the diode portion side mixed region is 1:1.

8. The semiconductor device according to claim 6, wherein when, in the trench extension direction, a length of the transistor region is greater than a length of the diode region in the mixed portion, in a trench arrangement direction, a width of the transistor portion side mixed region is greater than a width of the diode portion side mixed region.

9. The semiconductor device according to claim 6, wherein when, in the trench extension direction, a length of the transistor region is smaller than a length of the diode region in the mixed portion, in a trench arrangement direction, a width of the transistor portion side mixed region is smaller than a width of the diode portion side mixed region.

10. The semiconductor device according to claim 1, comprising:
an active region having the transistor portion and the diode portion; and
an edge termination structure portion provided on a periphery of the active region in a top view,
wherein the mixed portion is provided between an end of the diode portion and the edge termination structure portion in the trench extension direction.

11. The semiconductor device according to claim 10, wherein the diode portion has a dummy trench portion and a gate trench portion, and
the gate trench portion in the diode portion is provided to extend from the diode portion to the mixed portion.

12. The semiconductor device according to claim 1, comprising an accumulation region of the first conductivity type which is provided above the drift region and has a higher doping concentration than that of the drift region.

13. The semiconductor device according to claim 12, wherein the accumulation region is provided in each of the transistor portion, the mixed portion, and the diode portion.

14. The semiconductor device according to claim 1, comprising a back surface side lifetime control region provided on a back surface side of the semiconductor substrate.

15. The semiconductor device according to claim 1, comprising a front surface side lifetime control region provided on a front surface side of the semiconductor substrate,
wherein the front surface side lifetime control region extends from an end on the diode portion side of the mixed portion toward the transistor portion by 0 μm or more and 360 μm or less.

16. The semiconductor device according to claim 1, comprising a contact trench portion which extends from a front surface of the semiconductor substrate in a depth direction of the semiconductor substrate.

17. The semiconductor device according to claim 16, comprising a plug region of the second conductivity type which is provided below the contact trench portion and has a higher doping concentration than that of the base region.
